(19) United States
(12) Patent Application Publication
(10) Pub. No.: US 2013/0038989 A1
(43) Pub. Date: Feb. 14, 2013

(54) DETACHABLE COMPONENT RETAINER AND IMAGE DISPLAY SYSTEM HAVING THE SAME

(71) Applicant: HUI-CHIH CHANG, TAIPEI CITY (TW)

(72) Inventor: HUI-CHIH CHANG, TAIPEI CITY (TW)

(73) Assignee: NUETEQ TECHNOLOGY, INC., TAIPEI CITY (TW)

(21) Appl. No.: 13/463,676

(22) Filed: May 3, 2012

(30) Foreign Application Priority Data
Aug. 10, 2011 (TW) 100128532

(51) Int. Cl. H05K 7/00

(52) U.S. Cl. 361/679.01

(57) ABSTRACT

An image display system is provided, comprising a control unit, a display unit, a frame and at least one coupling unit. The display unit is connected electrically to the control unit, and the display unit has at least one index hole formed on the back surface thereof. The frame has at least one first fixed hole formed thereon, and the frame includes at least one first engaging member which corresponds to the index hole. Each of the first engaging members passes through the respective first fixed hole to insert into the corresponding index hole. Furthermore, each of the coupling units is sandwiched between the frame and the control unit in a detachable manner. Thus, a higher flexibility can be provided for the assembly of the control unit to the display unit.

### BACKGROUND OF THE INSTANT DISCLOSURE

1. Field of the Instant Disclosure

The instant disclosure relates to a detachable component retainer for an image display system, and pertains particularly to a display unit utilizing the detachable component retaining bracket for detachably mounting a control unit thereon.

2. Description of Related Art

In order for conventional image display system (e.g. desktop computers) to be aesthetically appealing and also to shorten the cabling distance, a control unit is typically affixed to the back surface of the display unit. For the main functions of the control unit generally include the receiving and transmitting of image signals to the display unit. However, the conventional method of fastening the control unit directly to the back of the display unit may cause uneasy dismantling of the control unit from the display unit.

Furthermore, in cases of maintenance or replacement, the control unit is dismantled directly from the display unit which may turn out to be very inconvenient. Other than that, the conventional fastening method may hinder the collocation of the control units with different types of display units (e.g. a wall mounted thin display) from easy assembling and dismantling.

To address the above issue, the inventor strives via industrial experience and academic research to present the instant disclosure, which can effectively improve the limitation described above.

SUMMARY OF THE INSTANT DISCLOSURE

The object of the instant disclosure is to provide a display unit having a detachable component retaining bracket, where a control unit on the back of the display unit can be easily assembled onto and detached from the display unit through the bracket.

In order to achieve the aforementioned objects, according to an embodiment of the instant disclosure, an image display system is provided, which comprises a control unit, a display unit, and a component retainer that includes a frame and at least one coupling unit. The display unit is connected electrically to the control unit, and by the orientation of the figure, the display unit has at least one index hole formed on the back surface thereof. The frame has at least one first fixed hole formed thereon, and the frame includes at least one first engaging member which corresponds to the index hole. Each of the first engaging members passes through the respective first fixed hole to insert into the corresponding index hole. Furthermore, each of the coupling units is sandwiched between the frame and the control unit in a detachable manner.

Based on the above, the image display system provided by the instant disclosure has a frame affixed thereto, where a coupling unit is attached to the frame for connection between the frame and a control unit. Thus, in cases of maintenance or replacement, the control unit can be dismantled simply by detaching from the frame, and thereby bringing fewer disturbances to the display unit. Furthermore, a higher flexibility can be provided for the assembly of the control unit through using the frame and the coupling unit.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1 shows a perspective view of an image display system according to a first embodiment of the instant disclosure;

FIG. 2 shows a perspective view of an image display system according to a second embodiment of the instant disclosure;

FIG. 3 shows a perspective view of an image display system according to a third embodiment of the instant disclosure;

FIG. 4 shows an exploded perspective view of an image display system according to a fourth embodiment of the instant disclosure;

FIG. 5 shows an assembled perspective view of the image display system according to a fourth embodiment of the instant disclosure;

FIG. 6 shows an exploded perspective view of an image display system according to a fifth embodiment of the instant disclosure.

### DETAILED DESCRIPTION OF THE PREFERRED EMBODIMENTS

### The First Embodiment

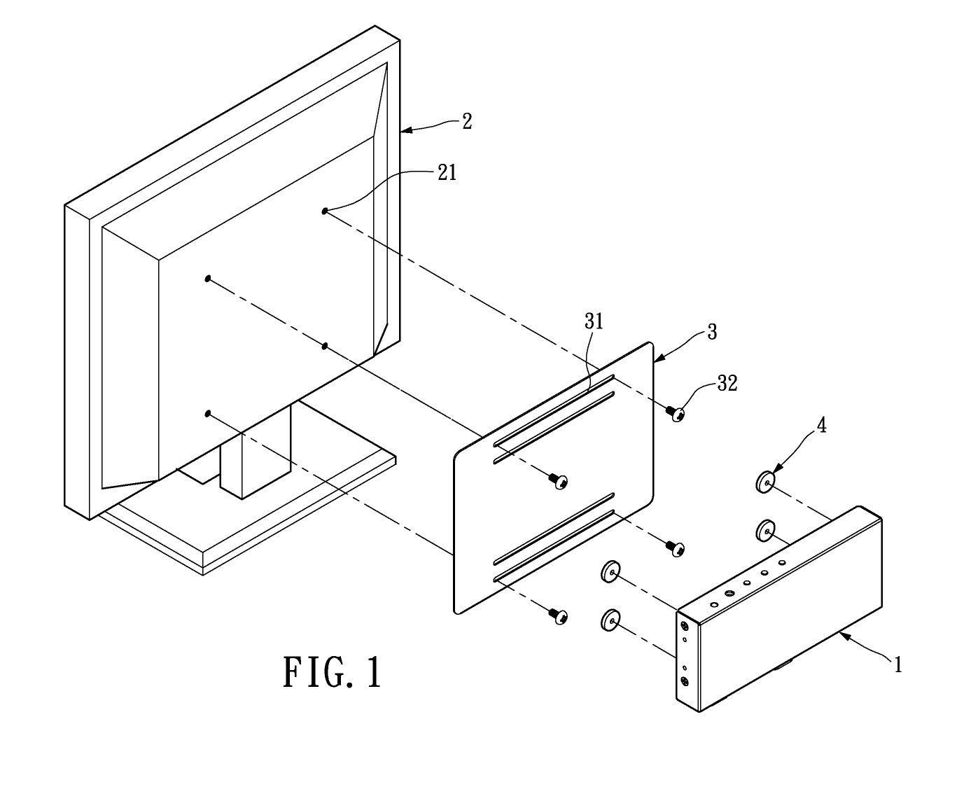

Please refer to FIG. 1, the instant disclosure provides an image display system, comprising a control unit 1, a display unit 2, a frame 3 and at least one coupling unit 4. The image display system in the instant exemplary embodiment is a desktop computer, however, this is not restricted thereto. For one thing, the image display system can be of various forms, such as a notebook, a tablet computer, or a video player (e.g. a Blu-ray player, a DVD player or a VCD player).

The control unit 1 is connected electrically to the display unit 2, and the control unit 1 can also vary according to practical needs, where the control unit can be selected from a group consisting of a switch, a splitter, a matrix, an extender, and a KVM. The control unit 1 receives and transmits image signals to the display unit 2. Since the switch, splitter, matrix, extender, or KVM belong to the signal processing devices of the prior arts, no further descriptions shall be provided herein.

The display unit 2 is a device capable of image displaying which includes, but not limited to, a flat panel display, a CRT display, a digital photo frame and an advertisement display panel where the display unit 2 may also vary according to practical needs. By the orientation of the figures, the surface where the display unit 2 displays images is defined as the front surface (not shown), where the back surface (not labeled) of the display unit 2 has at least one index hole 21 formed thereon. The instant embodiment has four index holes 21; however, the number of index holes 21 formed on the display unit 2 is not restricted thereto.

The frame 3 of the instant disclosure can be made of any material such as a metallic material, where the material thereof may vary according to the requirements. For the instant embodiment, the frame 3 is made of a permeable metallic material. Furthermore, the frame 3 has four first fixed holes 31 formed thereon, where the first fixed holes 31 can be an elongated or a circular shape, where the shape thereof is not limited thereto. The instant embodiment takes the first fixed holes 31 as an elongated shape for example. The frame 3 includes at least one first engaging member 32, where the first engaging member 32 is in correspondence to the index hole 21. Furthermore, the first engaging member 32 can be a screw or a nut for example. For the positioning of the first engaging member 32, it can be adjusted accordingly to the index hole 21 based on practical needs.

Each of the first engaging members 32 passes through the respective first fixed holes 31 to insert into corresponding index hole 21. In this way, the frame 3 will be screwed to the back of the display unit 2. Specifically speaking, in one of the exemplary embodiments, two of the first engaging members 32 are inserted into the same first fixed hole 31 proximate to the border of the frame 3; whereas in another exemplary embodiment, each of the first engaging members 32 are inserted into the respective first fixed hole 31. Therefore, the first engaging members 32 can selectively insert into the first fixed holes 31 according to the requirements where this is not restricted thereto. Furthermore, the aforementioned shapes of the first fixed holes 31 are meant only for referential purposes, where all shapes of the first fixed holes 31 are acceptable as long as the first engaging member 32 can be inserted therethrough.

The coupling unit 4 is sandwiched between the control unit 1 and the frame 3 in a detachable manner. Ideally, the coupling units 4 are made of magnetic materials, and the instant embodiment has four coupling units 4, however the number and material of the coupling units 4 are not limited thereto. The control unit 1 and the frame 3 of the instant disclosure are made of permeable metals such that they can be connected through the magnetic attraction of the coupling units 4. Thus, the frame 3 plays the role as a media in the aforementioned image display system. Specifically speaking, the frame 3 is affixed to the display unit 2 before the control unit 1 is affixed to the frame 3 through the coupling unit 4. Therefore, in cases of maintenance or replacement, the control unit 1 can be dismantled simply by detaching from the frame 3, and thereby bringing fewer disturbances to the display unit 2.

### The Second Embodiment

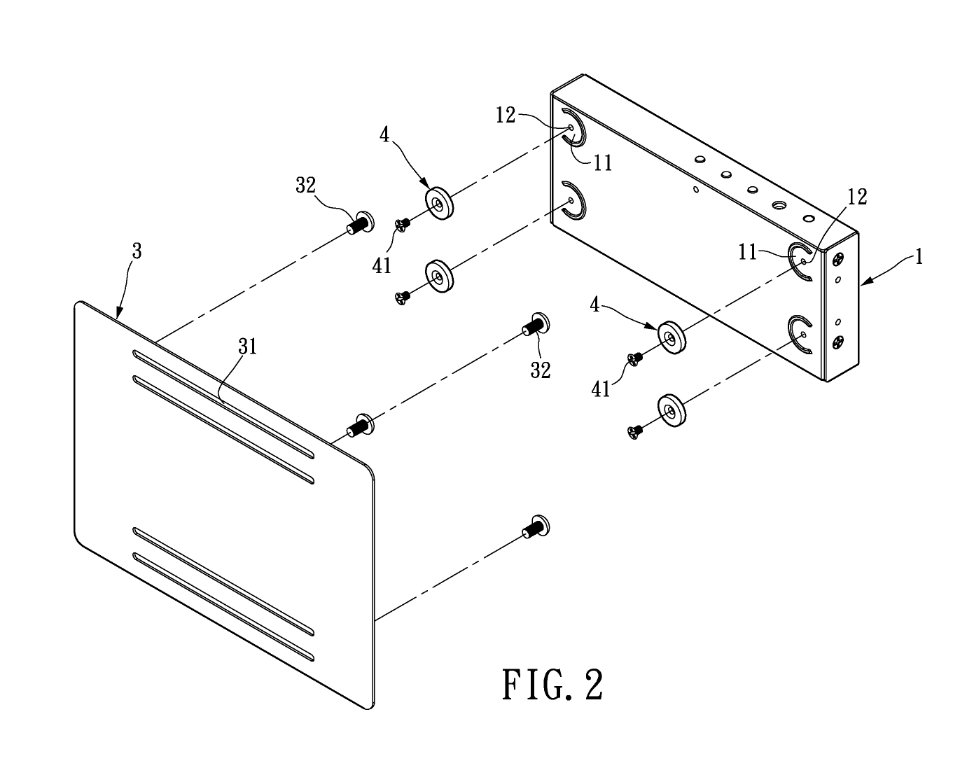

An image display system according to the second embodiment of the instant disclosure is as shown in FIG. 2. The difference between the instant embodiment and the preceding embodiment is that the control unit 1 in the instant embodiment has four fixing portions 11 formed thereon which are in correspondence to the coupling units 4 (herein referred to the magnets). The function of the fixing portions 11 is to provide connection to the coupling units 4, where each of the four coupling units 4 is connected to the respective fixing portion 11. Thus, the coupling units 4 can be fixed directly onto the control unit 1. In this way, the possibility of losing or the difficulty in finding the coupling units 4 during assembly can be reduced.

Furthermore, four first engaging holes 12 can be formed on the control unit 1 for connection of the coupling units 4 to the control unit 1. Specifically speaking, the coupling unit 4 is a hollow structure, where a screw 41 is inserted through the coupling unit 4 into the first engaging hole 12 of the control unit 1. Hence, the four coupling units 4 will be fastened to the four respective first engaging holes 12 by mean of screwing. In another exemplary embodiment, the coupling units 4 can be attached directly to the frame 3 through magnetic attraction. Thus, the coupling units 4 of the instant embodiment can be arranged selectively on the control unit 1 or the frame 3.

### The Third Embodiment

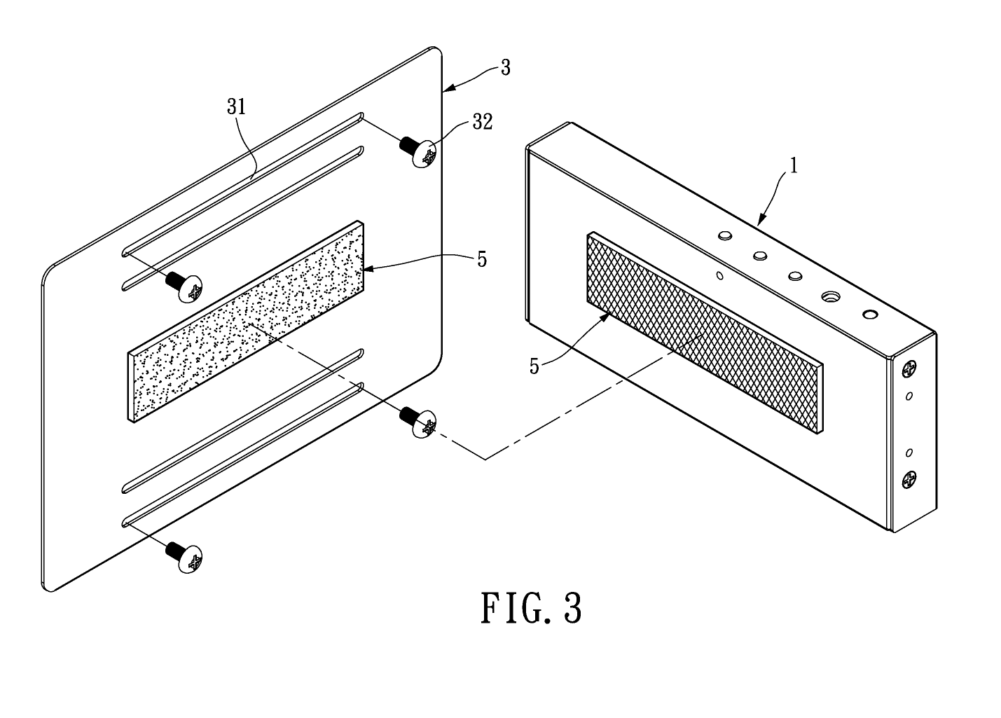

Please refer to FIG. 3 which shows an image display system according to the third embodiment of the instant disclosure. The difference between the instant embodiment and the preceding embodiment is that the frame 3 of the instant embodiment is made of a non-metallic material (such as a plastic-made frame 3). Therefore, the coupling units 4 will not be able to be attracted thereto. To overcome such condition, the instant embodiment further provides a coupling unit 4′, which particularly refers to an adhesive Velcro, for the connection. Specifically speaking, the coupling unit 4′ is attached on the corresponding positions on both control unit 1 and frame 3, and thereby the control unit 1 can be attached to the frame 3 through the coupling unit 4′.

### The Fourth Embodiment

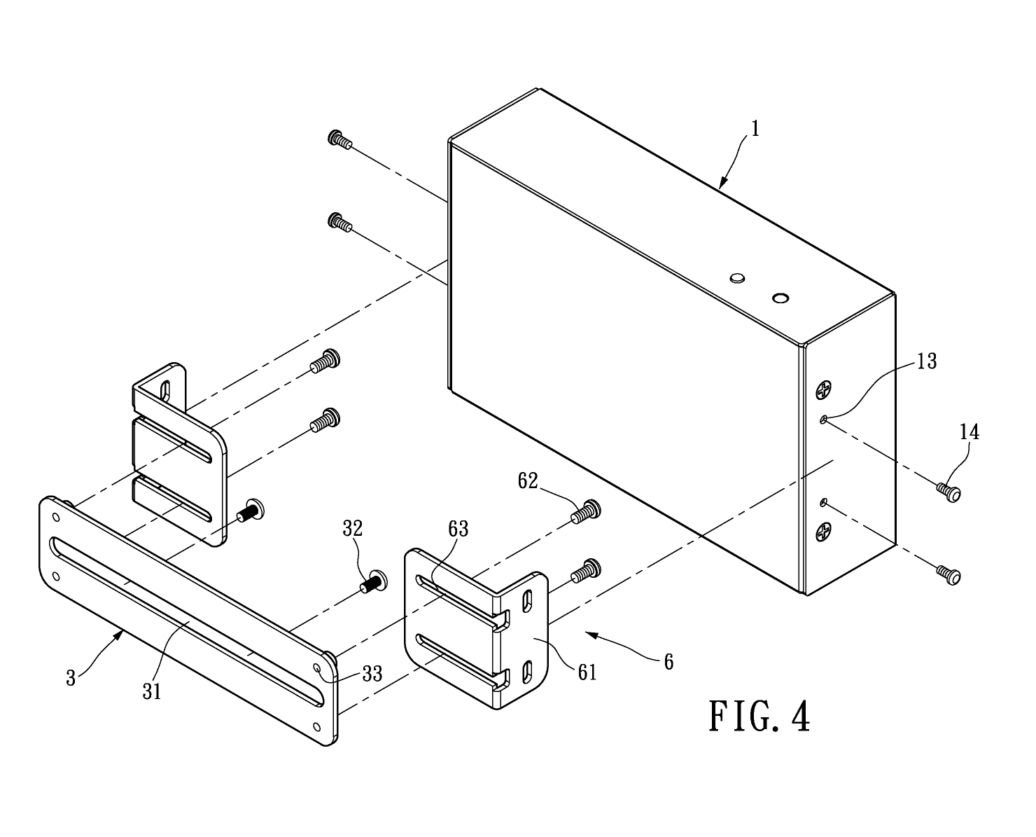

Please refer to FIG. 4 which shows an image display system according to the fourth embodiment of the instant disclosure. For the instant embodiment, the structural design of the frame 3 is a difference from the three preceding embodiments. Specifically speaking, the frame 3 has only one elongated first fixed hole 3 formed thereon, where the amount and shape of the frame 3 is not restricted thereto. Furthermore, the frame 3 is affixed to the display unit 2 (shown in FIG. 1) by passing the first engaging members 32 through the first fixed hole 31 to insert into the corresponding index holes 21 (shown in FIG. 1).

In addition, the instant embodiment provides a coupling unit 4″, including two L-brackets 41″ and four second engaging members 42″. Each of the L-brackets 41″ has two via holes 43″ formed thereon, where the via holes 43″ can be, but not limited to, an elongated or a circular shape. For the instant embodiment, the via holes 43″ are elongated shapes for example. To provide further explanations, the frame 3 has four second fixed holes 33 formed thereon, where the second fixed holes 33 are in correspondence to the second engaging members 42″. Each of the second engaging members 42″ passes through the respective via holes 43″ to insert into the corresponding second fixed holes 33, such that the coupling unit 4″ can be affixed to the frame 3. Furthermore, the shape of the via holes 43″ described above is only for referential purposes, where all designs of the via hole 43″ which enable the insertion of the second engaging members 42″ are acceptable.

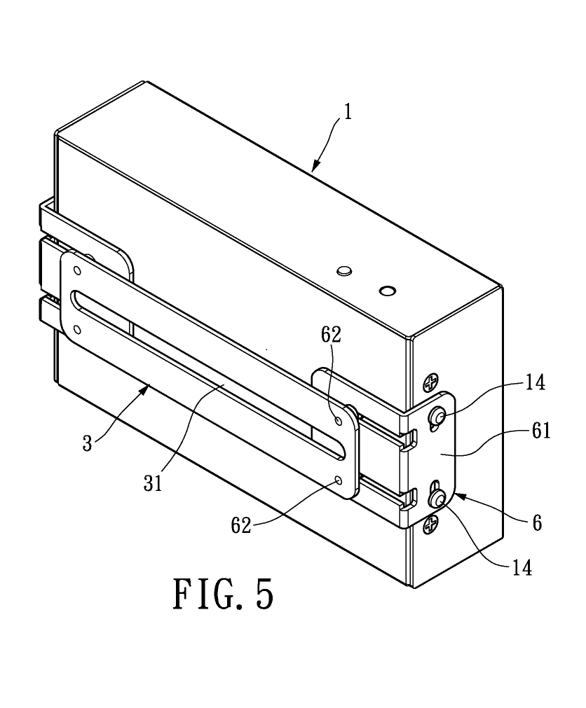

Specifically speaking, the two L-brackets 41″ are arranged on the two respective sides of the control unit 1, and there is at least one through hole (not labeled) formed on each L-bracket 41″. Furthermore, each of the two sides of the control unit 1 has at least one second engaging hole 13 formed respectively thereon, where the second engaging holes 13 are in correspondence to the through holes (not labeled) of the L-brackets 41″. Next, the coupling unit 4″ is fastened to the control unit 1 by inserting a screw 14 through the through hole (not labeled) and into the respective second engaging hole 13. With reference to FIG. 5, an assembled view of the coupling unit 4″ to the control unit 1 is shown. Thus, in cases of maintenance or replacement, the control unit 1 can be easily detached by unscrewing the screws 14.

### The Fifth Embodiment

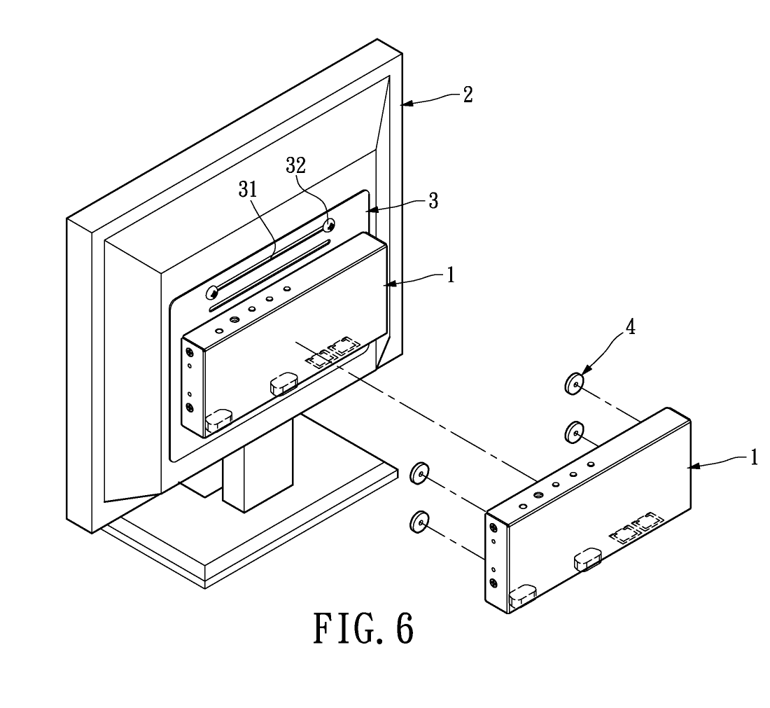

Please refer to FIG. 6 which shows an image display system according to the fifth embodiment of the instant disclosure. The difference between the instant embodiment and the first embodiment is that a plurality of control units 1 can be affixed to the display unit according to practical needs. For the instant embodiment, there are, but not limited to, two control units 1 for example, where the two control units 1 are in connection through the aforementioned coupling unit 4, and the two control units 1 are in electrical connection through a wire or a cable for instance. However, the two control units 1 can also be fastened by using the coupling unit 4′, the coupling unit 4″ or the collocations thereof, where the fastening method is not restricted thereto.

Based on the above, for the image display system of the instant exemplary embodiment, the frame is affixed to the display before the control unit is affixed to the frame through the coupling units. Therefore, in cases of maintenance or replacement, the control unit can be dismantled simply by detaching from the frame, and thereby bringing fewer disturbances to the display. Furthermore, a higher flexibility can be provided for the assembly of the control unit through using the frame and the coupling unit.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. An image display system, comprising:
a control unit;
a display unit connected electrically to the control unit, where at least one index hole is formed on the back surface of the display unit; and
a component retainer including:
a frame having at least one first fixed hole formed thereon, wherein the frame includes at least one first engaging member corresponding to the index hole, and the first engaging member passes through the first fixed hole to insert into the index hole, and at least one coupling unit coupling between the frame and the control unit in a detachable manner.

2. The image display system according to claim 1, wherein the engaging member is a magnet.

3. The image display system according to claim 2, wherein the control unit further comprises at least one fixing portion formed thereon, wherein the fixing portion is in correspondence to the coupling unit, such that the coupling unit can be connected thereto.

4. The image display system according to claim 2, wherein the control unit further comprises at least one first engaging hole formed thereon for connection of the coupling unit to the control unit, where the coupling unit is fastened to the control unit by inserting a screw into the first engaging hole.

5. The image display system according to claim 1, wherein the coupling unit is Velcro, and the coupling unit is attached on the corresponding positions of both control unit and frame.

6. The image display system according to claim 1, wherein the coupling unit includes at least one L-bracket and at least one second engaging member.

7. The image display system according to claim 6, wherein the second engaging member is a screw, and the frame has at least one second fixed hole formed thereon, where the second fixed hole is in correspondence to the second engaging member, the L-bracket is fastened to the frame by inserting the second engaging member into the second fixed hole.

8. The image display system according to claim 7, wherein the control unit has at least one second engaging hole formed thereon for connection of the L-bracket to the control unit by mean of screwing.

9. The image display system according to claim 1, wherein the first engaging member is a screw.

10. The image display system according to claim 1, further comprising an additional control unit, where the two control units are in connection through the coupling unit, and the two control units are in electrical connection.

11. The image display system according to claim 10, wherein the additional control unit can be selected from a group consisting of a switch, a splitter, a matrix, an extender, and a KVM

12. The image display system according to claim 1, wherein the display unit can be selected from a group consisting of a flat panel display, a CRT display, a digital photo frame and an advertisement display panel.
